(19) United States
(12) Patent Application Publication
(10) Pub. No.: US 2019/0326900 A1
(43) Pub. Date: Oct. 24, 2019

(54) DRIVER CIRCUIT FOR A DEVICE CIRCUIT

(71) Applicant: Infineon Technologies AG, Neubiberg (DE)

(72) Inventors: Rocco Calabro, Villach (AT); Oleg Vitrenko, Villach (AT)

(21) Appl. No.: 15/960,807

(22) Filed: Apr. 24, 2018

(51) Int. Cl. H03K 17/10; H03K 17/06

(52) U.S. Cl. CPC H03K 17/107; H03K 17/06

(57) ABSTRACT

A driver circuit for driving a device circuit, including: a diode-connected transistor having a bulk input coupled to a driver supply voltage, coupled between the driver supply voltage and a positive control node, wherein the driver supply voltage is less than a threshold voltage of the device circuit; a capacitor coupled between the positive control node and a signal input, wherein when an input signal received at the signal input is high, a positive control voltage at the positive control node configured to control an input transistor of the device circuit is higher than the threshold voltage of the device circuit.

### BACKGROUND

Mixed signal circuits may require signals to be converted from a digital supply domain to an analog supply domain, which typically has a higher magnitude. This conversion becomes problematic when the digital supply voltage is near or below a threshold voltage of analog devices. In particular, it is difficult to achieve this conversion with acceptable performance when area, power, and robustness concerns are paramount.

Level shifters that have multiple stages or a cascaded input require an additional supply/bias voltage. For a two-stage level shifter there is an additional supply voltage for the first stage, and for a cascaded input level shifter there is a bias voltage. The additional supply/bias voltage results in increased area, power consumption, and routing complexity, and also possible crosstalk path between different level shifters.

### BRIEF DESCRIPTION OF THE DRAWINGS

FIG. 1 illustrates a mixed signal circuit comprising a driver circuit configured to drive a device circuit in accordance with aspects of the disclosure.

FIG. 2A illustrates a cross-section of a diode-connected NMOS device during a charging phase.

FIG. 2B illustrates a cross-section of a diode-connected NMOS device during a boosting phase.

FIG. 3 illustrates a more detailed example of a mixed signal circuit comprising a driver circuit configured to drive a device circuit in accordance with aspects of the disclosure.

FIG. 4 illustrates a flowchart of a method of the driver circuit driving the device circuit of FIG. 1 in accordance with aspects of the disclosure.

### DETAILED DESCRIPTION

The present disclosure is directed to a driver circuit configured to boost a digital input signal voltage to a level higher than that of a threshold voltage of analog devices.

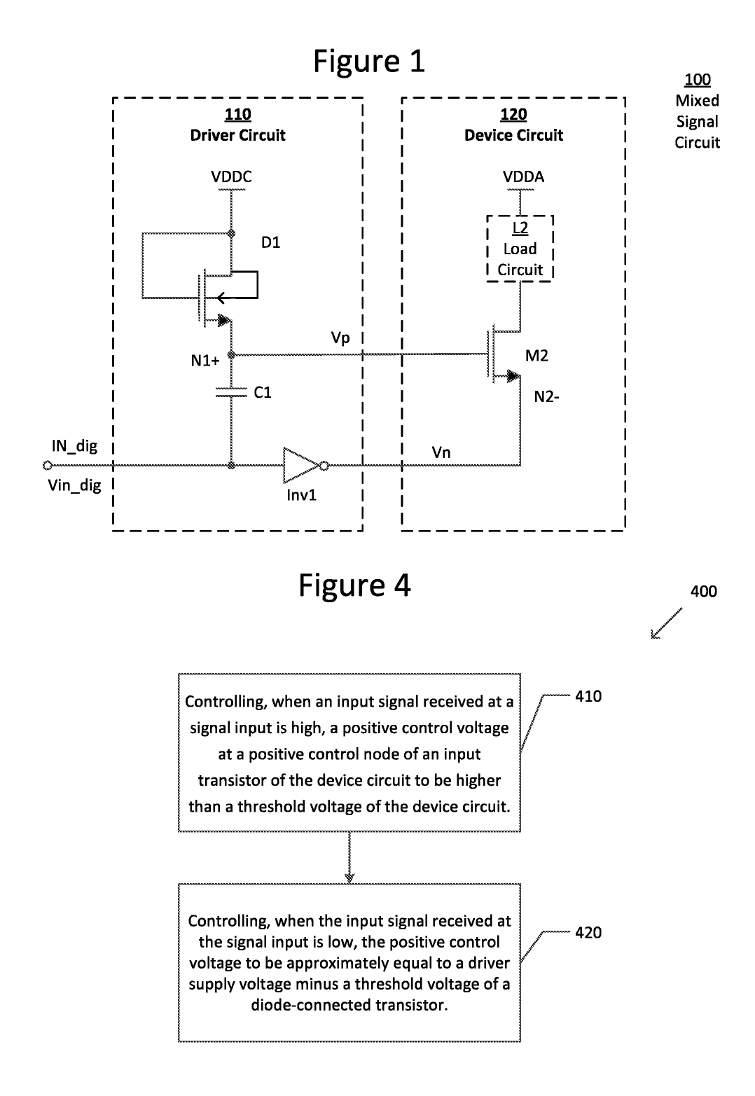

FIG. 1 illustrates a mixed signal circuit 100 comprising a driver circuit 110 configured to drive a device circuit 120 in accordance with aspects of the disclosure.

The driver circuit 110 comprises a diode-connected transistor D1, a capacitor C1, and an inverter Inv1. The driver circuit 110 is in the digital supply domain and is supplied by a driver supply voltage VDDC. The driver supply voltage VDDC may be, for example, less than 1V.

A diode-connected transistor is constructed from a diode out of a four-terminal transistor. Using a Metal-Oxide-Semiconductor Field-Effect Transistor (MOSFET), the diode-connected transistor is constructed by connecting the gate, drain, and bulk together.

The device circuit 120 comprises an input transistor M2 and a load circuit L2. The load circuit L2 is coupled between a device supply voltage VDDA and the input transistor M2. The load circuit L2 may be a resistor or a controlled current source, for example. If the mixed signal circuit 100 is a differential signal circuit, the load circuit L2 may comprise cross-coupled transistors. The device circuit 120 is in the analog supply domain and is supplied by the device supply voltage VDDA. The device supply voltage VDDA may be, for example, 5V. Also, the driver circuit 110 and the device circuit 120 may be arranged on a same semiconductor die.

The diode-connected transistor D1 is an NMOS device, has a bulk input coupled to a driver supply voltage VDDC, and is coupled between the driver supply voltage VDDC and a positive control node N1+. The capacitor C1 is coupled between the positive control node N1+ and a signal input IN_dig, which receives a digital input signal Vin_dig. The inverter circuit Inv1, which is coupled between the signal input IN_dig and a negative control node N2− of the input transistor M2 of the device circuit 120, is configured to invert a logic value of the input signal Vin_dig. The driver supply voltage VDDC is less than a threshold voltage of analog devices of the device circuit 120. The threshold voltage of the analog devices may be, for example, 1V or more.

By way of an operational overview, the capacitor C1 boosts the voltage Vp at the positive input node N1+. When the input signal Vin_dig at the signal input IN_dig goes low, the driver circuit 110 controls the source of the input transistor M2 to go high to switch the input transistor M2 completely off; this results in a state in which the capacitor C1 is charged with the diode-connected transistor D1. When the input signal Vin_dig goes high, the source of the input transistor M2 goes low, and the gate of the input transistor M2 is boosted to a voltage level higher than the threshold voltage of the analog device circuit 120.

More specifically, when an input signal Vin_dig received at the signal input IN_dig is high, there is a boosting phase and a charging phase. The boosting phase occurs when there is a low to high transition of the input signal Vin_dig received at the signal input IN_dig. Conversely, the charging phase occurs when there is a high to low transition of the input signal Vin_dig received at the signal input IN_dig.

During the boosting phase (low to high transition of Vin_dig), a positive control voltage Vp at the positive control node N1+ is higher than the threshold voltage of the analog device circuit 120. The control voltage Vp at the positive control node N1+ is approximately double the driver supply voltage VDDC minus a threshold voltage Vth_dig of the diode-connected transistor D1 (i.e., Vp=2*VDDC−Vth_dig). A negative control voltage Vn at a negative control node N2− of the input transistor M2 is approximately equal to a driver ground voltage VSSC. There is then a differential voltage between voltage Vp and voltage Vn of 2*VDDC−Vth_dig, which is always higher than the driver supply voltage VDDC since the threshold of the analog devices must be lower than the driver digital supply voltage VDDC to allow operation of the digital circuitry.

During the charging phase (high to low transition of Vin_dig), when a voltage Vp at the positive control node N1+ is less than the driver supply voltage VDDC minus a threshold voltage Vth_dig of the diode-connected transistor D1 (i.e., when Vp<VDDC−Vth_dig), the diode-connected transistor D1 charges the capacitor C1.

When the input signal Vin_dig received at the signal input IN_dig is low, the control voltage Vp at the positive control node N1+ is approximately equal to the driver supply voltage VDDC minus a threshold voltage Vth_dig of the diode-connected transistor D1 (i.e., Vp=VDD−Vth_dig). A negative control voltage Vn at the negative control node N2− of the input transistor M2 is approximately equal to the driver supply voltage VDDC (i.e., Vn=VDDC). There is a differential voltage between voltage Vp and voltage Vn of a negative threshold voltage −Vth_ana of the input transistor M2. The differential signal Vp-Vn, which then has a higher magnitude compared to the original input signal Vin_dig, thereby potentially allowing the driving of the analog devices.

The driver circuit 110 keeps its logic value, even when the capacitor C1 is discharged at its minimum value VDDC-Vth_dig. In fact, if the input signal Vin_dig is high and the capacitor C1 is discharged to VDDC-Vth_dig, the differential voltage between voltages Vp and Vn is VDDC-Vth_dig, thereby allowing the input transistor M2 to keep conducting in subthreshold. If the input signal Vin_dig is instead low, the differential voltage between voltages Vp and Vn is a negative threshold voltage −Vth_ana of the input transistor M2, and thus the input transistor M2 is switched completely off.

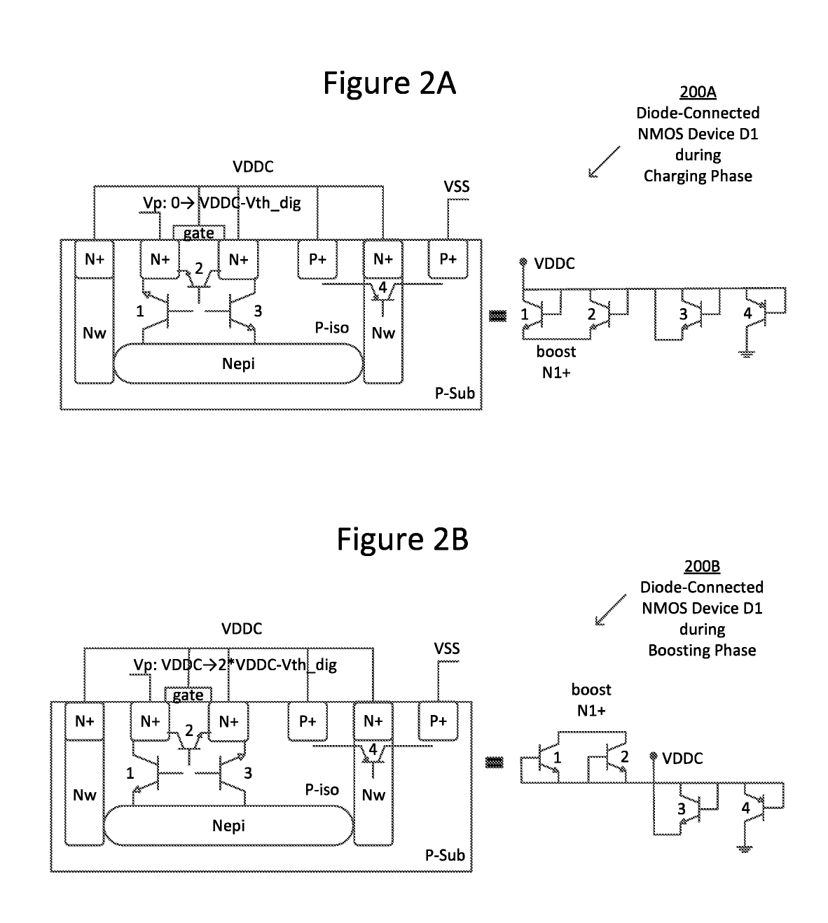

FIGS. 2A and 2B illustrate a cross-section of the diode-connected NMOS device D1, FIG. 2A during a charging phase, and FIG. 2B during a boosting phase. For each of these figures, an equivalent circuit is shown.

The parasitic bipolar transistors of the diode-connected NMOS D1 are statically coupled to the driver supply voltage VDDC and thus shorted. No parasitic path is created, and therefore charging pumps for well control are not needed as the wells Nw do not float. Not having moving wells is advantageous in terms of power and speed. Also, an NMOS diode consumes less power and area as compared with a PMOS diode or another active switch due to the fact that only the small-area drain changes its potential.

FIG. 2A illustrates the diode-connected NMOS device D1 during a charging phase when the capacitor C1 is below the driver supply voltage VDDC. The positive control voltage Vp ranges from 0 to the driver supply voltage VDDC-Vth_dig. In this charging phase, parasitic bipolar transistor 1 has its emitter coupled to the N-diffusion N+ and its collector coupled to the epitaxial layer Nepi. The parasitic bipolar transistors 1 and 2 charge the capacitor C1 together with the NMOS channel to the driver supply voltage VDDC minus one digital device threshold Vth_dig, which is not the case with a charge pump where frequency and bulk control are required.

FIG. 2B illustrates the diode-connected NMOS device D1 during a boosting phase when the capacitor C1 is above the driver supply voltage VDDC. The positive control voltage Vp is higher than the drive supply voltage VDDC. In this boosting phase, parasitic bipolar transistor 1 has its collector coupled to the N-diffusion N+ and its emitter coupled to the epitaxial layer Nepi. In this configuration all bipolars have their bases and emitters shorted to VDDC, which makes all of them not conducting.

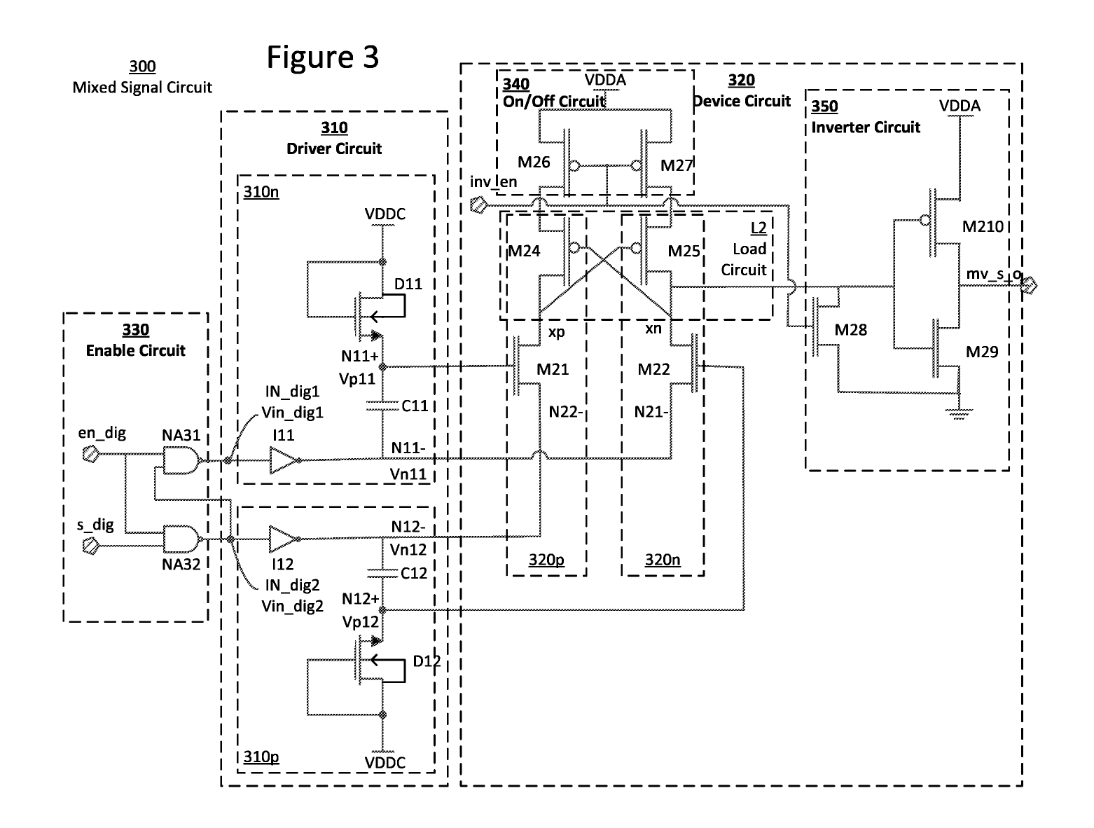

FIG. 3 illustrates a more detailed example of a mixed signal circuit 300 comprising a driver circuit 310 configured to drive a device circuit 320 in accordance with aspects of the disclosure.

This mixed signal circuit 300 is similar to the mixed signal circuit 100 of FIG. 1, except that this circuit 300 is a differential circuit.

The mixed signal circuit 300 comprises a driver circuit 310, a device circuit 320, an enable circuit 330, an on/off circuit 340, and an inverter circuit 350.

The driver circuit 310 comprises complementary driver circuits 310n and 310p. Each of the complementary driver circuits 310n and 310p is similar to the driver circuit 110 of FIG. 1. For the sake of brevity, the details of these complementary circuits will be omitted here.

The device circuit 320 comprises complementary device circuits 320n and 320p. Each of the complementary device circuits 320n and 320p is similar to the device circuit 120 of FIG. 1. For the sake of brevity, the details of these complementary circuits will be omitted here. The load circuit L2 of this device circuit 320 comprises cross-coupled transistors M25, M24 which have a polarity opposite that of the first and second input transistors M21, M22. In this example, the input transistors M21, M22 are NMOS transistors, and the cross-coupled transistors M24, M25 are PMOS transistors.

The enable circuit 330 comprises a first NAND gate NA31 and a second NAND gate N32. The second NAND gate NA32 is configured to receive an enable signal at an enable signal input en_dig and an input signal from the signal input s_1. The first NAND gate NA31 is configured to receive the enable signal from the enable signal input en_dig and an output of the second NAND gate NA32

The on/off circuit 340 comprises transistors M26 and M27, and is configured to switch the load circuit L2 on and off. In this example, the transistors M26 and M27 are PMOS transistors.

The inverter circuit 350 comprises transistors M28, M209, and M210. The inverter circuit 350 is configured to invert an output signal of the load circuit L2, and output an inverted version at the signal output mv_s_o.

During operation of the driver circuit 310, when a first of a pair of differential input signals Vin_dig1 received at the first differential signal input IN_dig1 of the driver circuit 310 is high and a second of the pair of differential input signals Vin_dig2 received at the second differential signal input IN_dig2 is low, a first positive control voltage Vp11 at the first positive control node N11+ to control the first input transistor M21 is higher than the threshold voltage of the device circuit 320, a second positive control voltage Vp12 at the second positive control node N12+ to control the second input transistor M22 is approximately equal to the driver supply voltage VDDC minus a threshold voltage Vth_dig11 of the first diode-connected transistor D11 (i.e., Vp12=VDDC−Vth_dig11), a first negative control voltage Vn11 at a first negative control node N11- to control the first input transistor M21 of the device circuit 320 is approximately equal to a driver ground voltage, and a second negative control voltage Vn12 at a second negative control node N12- to control the second input transistor M21 of the device circuit 320 is approximately equal to the driver supply voltage VDDC (i.e., Vn12=VDDC).

When the first of the pair of differential input signals Vin_dig1 received at the first differential signal input IN_dig1 of the driver circuit 310 is low and the second of the pair of differential input signals Vin_dig2 received at the second differential signal input IN_dig2 is high, the first positive control voltage Vp11 at the first positive control node N11+ is approximately equal to the driver supply voltage VDDC minus the threshold voltage Vth_dig of the diode-connected transistor D11 (i.e., Vp11=VDDC−Vth_dig11), the second positive control voltage Vp12 at the second positive control node N12+ is higher than the threshold voltage of the device circuit 320, the first negative control voltage Vn11 at the first negative control node N11− is approximately equal to the driver supply voltage VDDC (i.e., Vn11=VDDC), and the second negative control voltage Vn12 at the second negative control node N12− is approximately equal to the driver ground voltage.

Considering operation of the mixed signal circuit 300 as a whole, in the disabled condition (i.e., when inverter enable signal inv_en controlling transistor M28 is high and digital enable signal en_dig is low), the driver circuit 310 pulls both nodes N11- and N12− low. At the same time, the first capacitor C11 is charged by the diode-connected transistor D11 to bring the voltage Vp11 at node N11+ to a voltage level VDDC−Vth_dig11. Similarly, the second capacitor C12 is charged by the diode-connected transistor D12 to bring the voltage Vp12 at node N12+ to a voltage level VDDC−Vth_dig12.

Once the driver circuit 310 is enabled (i.e., when the inverter enable signal inv_en is low, and digital enable signal en_dig is high), the voltage Vp12 at node N12+follows the digital input signal s_dig, and the voltage Vn11 at node N11− is the negation of the digital input signal s_dig. If the digital input signal s_dig is high, the voltage Vp12+ at node N12+ is shifted up by the driver supply voltage VDDC, reaching a voltage of 2*VDDC-Vth_dig12, and the voltage Vp11 at node N11+will instead remain at a VDDC-Vth_dig11. The input transistors M21 and M22 then experience a gate-source voltage of −Vth_ana and 2*VDDC-Vth_ana, respectively, which switches input transistor M22 on and input transistor M21 off, setting a latch formed by cross-coupled transistors M24 and M25 and hence the output voltage mv_s_o to high. Exactly the opposite happens when the input signal s_dig changes its logic value to low. In this case, the voltage Vp11 at node N11+ is shifted up, reaches VDDC−Vth_dig11, and the voltage Vp12 at node N12+ is pushed down to VDDC−Vth_dig11. The input transistor M22 has a gate-source voltage of −Vth_dig to switch transistor M22 off, and the input transistor M21 has a gate-source voltage 2*VDDC−Vth to switch transistor M21 on, setting the latch formed by cross-coupled transistors M24 and M25 and the output signal mv_s_o to low.

A condition for the functionality of the device circuit 320 is that 2*VDDC−Vth_dig is higher than the threshold voltage Vth_ana of the analog devices. This condition is typically more relaxed as compared with a traditional topology condition of high_dig being higher than Vth_ana since in order to maintain the functionality of the digital driver circuit 310, the driver supply voltage VDDC is always higher than the digital device threshold voltage Vth_dig.

The device circuit 320 operates correctly in both dynamic and static conditions, provided there is a correct state at startup. The state of the device circuit 320 is kept static when both capacitors C11 and C12 are discharged to the driver supply voltage VDDC minus the digital device threshold voltage Vth_dig (i.e., VDDC−Vth_dig), since either transistor M21 or transistor M22 has its source at the digital supply voltage VDDC providing a gate-source voltage of minus the digital threshold voltage (−Vth_ana). The other transistor of M21 and M22 in worst case is conducting in subthreshold, having a gate-source voltage of the driver supply voltage VDDC minus the digital device threshold voltage (i.e., VDDC−Vth_dig), which is practically always higher than 0.

FIG. 4 illustrates a flowchart 400 of a method of the driver circuit driving the device circuit of FIG. 1 in accordance with aspects of the disclosure.

At 410, controlling, when an input signal Vin_dig received at the signal input IN_dig is high, a positive control voltage Vp at the positive control node N1+ of the input transistor M2 of the device circuit 120 to be higher than a threshold voltage of the device circuit 120.

At 420, controlling, when the input signal Vin_dig received at the signal input IN_dig is low, the positive control voltage Vp at the positive control node N1+ to be approximately equal to the driver supply voltage VDDC minus a threshold voltage Vth_dig of a diode-connected transistor D1.

The driver circuit of this disclosure may be embodied in any mixed signal circuit where a driver supply voltage reaches levels near or below a threshold voltage of analog devices. The driver circuit does not require an additional supply/bias voltage. The driver circuit is single stage, which is faster than a multi-stage driver circuit as each stage results in a delay. Also, the driver circuit does not have a high frequency as large wells with parasitic capacitors are instead static.

While the foregoing has been described in conjunction with exemplary embodiment, it is understood that the term “exemplary” is merely meant as an example, rather than the best or optimal. Accordingly, the disclosure is intended to cover alternatives, modifications and equivalents, which may be included within the scope of the disclosure.

Although specific embodiments have been illustrated and described herein, it will be appreciated by those of ordinary skill in the art that a variety of alternate and/or equivalent implementations may be substituted for the specific embodiments shown and described without departing from the scope of the present disclosure. This disclosure is intended to cover any adaptations or variations of the specific embodiments discussed herein.

1. A driver circuit for driving a device circuit, comprising:
a diode-connected transistor having its bulk input coupled to its drain, and coupled between a driver supply voltage and a positive control node, wherein the driver supply voltage is less than a threshold voltage of the device circuit; and
a capacitor coupled between the positive control node and a signal input,
wherein when an input signal received at the signal input is high, a positive control voltage at the positive control node configured to control an input transistor of the device circuit is higher than the threshold voltage of the device circuit.

2. The driver circuit of claim 1, wherein when the input signal received at the signal input is high, the control voltage at the positive control node is approximately double the driver supply voltage minus a threshold voltage of the diode-connected transistor.

3. The driver circuit of claim 1, wherein the diode-connected transistor is configured to charge the capacitor when a voltage at the positive control node is less than the driver supply voltage minus a threshold voltage of the diode-connected transistor.

4. The driver circuit of claim 1, wherein when the input signal received at the signal input is low, the control voltage at the positive control node is approximately equal to the driver supply voltage minus a threshold voltage of the diode-connected transistor.

5. The driver circuit of claim 1, further comprising:
an inverter circuit coupled between the signal input and a negative control node of the input transistor of the device circuit, and configured to invert the input signal.

6. The driver circuit of claim 1, wherein when the input signal received at the signal input is high, a negative control voltage at a negative control node of the input transistor is approximately equal to a driver ground voltage.

7. The driver circuit of claim 1, wherein when the input signal received at the signal input is low, a negative control voltage at a negative control node of the input transistor is approximately equal to the driver supply voltage.

8. A semiconductor circuit, comprising:
a device circuit, comprising:
an input transistor; and
a load circuit coupled between a device supply voltage and the input transistor; and
a driver circuit, comprising:
a diode-connected transistor having a bulk input coupled to a driver supply voltage, and coupled between the driver supply voltage and a positive control node, wherein the driver supply voltage is less than a threshold voltage of the device circuit; and
a capacitor coupled between the positive control node and a signal input,
wherein when an input signal received at the signal input is high, a differential control voltage between the positive and a negative control nodes configured to control the input transistor of the device circuit is higher than the threshold voltage of the device circuit.

9. The semiconductor circuit of claim 9, wherein the driver circuit further comprises:
an inverter circuit coupled between the signal input and the negative control node of the input transistor, and configured to invert the input signal,
wherein when the input signal received at the signal input is high, a negative control voltage of the negative control node of the input transistor is approximately equal to a driver ground voltage.

10. The semiconductor circuit of claim 8, wherein the driver circuit and the device circuit are arranged on a same semiconductor die.

11. The semiconductor circuit of claim 8, wherein the load circuit is a resistor or a controlled current source.

12. The semiconductor circuit of claim 8, wherein the semiconductor circuit is a differential signal circuit.

13. The semiconductor circuit of claim 12, wherein the load circuit is a cross-coupled transistor circuit.

14. A semiconductor circuit, comprising:
a device circuit, comprising:
a first input transistor;
a second input transistor; and
a load circuit comprising cross-coupled transistors coupled between a device supply and the first and second input transistors, wherein the cross-coupled transistors have a polarity opposite that of the first and second input transistors; and
a driver circuit configured to drive the device circuit, comprising:
a first diode-connected transistor having its bulk input coupled to its drain, and coupled between a driver supply voltage and a first positive control node, wherein the driver supply voltage is less than a threshold voltage of the device circuit;
a second diode-connected transistor having a bulk input coupled to the driver supply voltage, and coupled between the driver supply voltage and a second positive control node;
a first capacitor coupled between the first positive control node and a first differential signal input; and
a second capacitor coupled between the second positive control node and a second differential signal input,
wherein when a first of a pair of differential input signals received at the first differential signal input is high and a second of the pair of differential input signals received at the second differential signal input is low, a first positive control voltage at the first positive control node configured to control the first input transistor of the device circuit is higher than the threshold voltage of the device circuit, a second positive control voltage at the second positive control node to control the second input transistor is approximately equal to the driver supply voltage minus a threshold voltage of the first diode-connected transistor, a first negative control voltage at a first negative control node configured to control the first input transistor of the device circuit is approximately equal to a driver ground voltage, and a second negative control voltage at a second negative control node configured to control the second input transistor of the device circuit is approximately equal to the driver supply voltage.

15. The semiconductor circuit of claim 14, wherein when the first of the pair of differential input signals received at the first differential signal input is low and the second of the pair of differential input signals received at the second differential signal input is high, the first positive control voltage at the first positive control node is approximately equal to the driver supply voltage minus the threshold voltage of the first diode-connected transistor, the second positive control voltage at the second positive control node is higher than the threshold voltage of the device circuit, the first negative control voltage at the first negative control node is approximately equal to the driver supply voltage, and the second negative control voltage at the second negative control node is approximately equal to the driver ground voltage.

16. A method of a driver circuit driving a device circuit, comprising:
controlling, when an input signal received at a signal input is high, a positive control voltage at a positive control node of an input transistor of the device circuit to be higher than a threshold voltage of the device circuit,
wherein the driver circuit comprises:
the diode-connected transistor having its bulk input coupled to its drain, and coupled between a driver supply voltage and the positive control node, wherein the driver supply voltage is less than the threshold voltage of the device circuit; and
a capacitor coupled between the positive control node and the signal input.

17. The method of claim 16, further comprising:
controlling, when the input signal received at the signal input is low, the positive control voltage to be approximately equal to a driver supply voltage minus a threshold voltage of a diode-connected transistor.
